(19) United States
(12) Patent Application Publication
(10) Pub. No.: US 2011/0018752 A1
(43) Pub. Date: Jan. 27, 2011

(54) FLASH A/D CONVERTER, FLASH A/D CONVERSION MODULE, AND DELTA-SIGMA A/D CONVERTER

(75) Inventors: Masao TAKAYAMA, Hyogo (JP); Kazuo Matsukawa, Osaka (JP); Yosuke Mitani, Osaka (JP); Shiro Dosho, Osaka (JP)

Correspondence Address: MCDERMOTT WILL & EMERY LLP, 600 13TH STREET, NW, WASHINGTON, DC, 20005-3096, US

(73) Assignee: Panasonic Corporation, Osaka (JP)

(21) Appl. No.: 12/899,154

(22) Filed: Oct. 6, 2010

Related U.S. Application Data
(63) Continuation of application No. PCT/JP2009/001887, filed on Apr. 24, 2009.

(30) Foreign Application Priority Data
May 8, 2008 (JP) 2008-122653

(51) Int. Cl. H03M 3/00; H03M 1/36

(52) U.S. Cl. 341/143; 341/159

(57) ABSTRACT

In a flash A/D converter, a predictor predicts next analog input data based on a digital output signal from an A/D converter, and outputs prediction data. Based on the prediction data from the predictor, a controller turns on comparators having reference voltages near the prediction data, and in order to ensure a certain degree of A/D conversion accuracy even when the prediction fails, also turns on even-numbered comparators 103.2a (where a is 0 to 7), for example. In this manner, even when prediction of next analog input data fails, a 4-bit A/D converter can perform A/D conversion with 3-bit accuracy, while saving power consumption by reducing the number of comparators to be turned on.

### CROSS-REFERENCE TO RELATED APPLICATION

This is a continuation of PCT International Application PCT/JP2009/001887 filed on Apr. 24, 2009, which claims priority to Japanese Patent Application No. 2008-122653 filed on May 8, 2008. The disclosures of these applications including the specifications, the drawings, and the claims are hereby incorporated by reference in their entirety.

### BACKGROUND

The present disclosure relates to reduction of power consumption of flash analog-to-digital (A/D) converters.

As a technique for converting an analog signal into a digital signal, flash A/D converters having simple configurations and high conversion speeds have been employed. A flash A/D converter needs comparators in a number obtained by subtracting 1 from 2^{m} (i.e., 2^{m}−1) where m is a quantization bit rate. Accordingly, as the quantization bit rate m increases, the number of required comparators disadvantageously increases exponentially. The increase in the number of comparators increases power consumption.

To reduce the increase in power consumption, the technique of operating only a group of predicted comparators and not operating the other comparators was proposed. This technique is shown in, for example, U.S. Pat. No. 6,081,219, and will be described with reference to FIG. 6. In FIG. 6, a predictor 102 calculates the next digital code based on prediction using a previous digital output signal 111 from a converter 101, and adjusts the number of comparators to be used (i.e., turned on) among all the comparators 103.01-103.15 included in a comparator array 103 such that A/D conversion can be accurately performed using the predicted value. Specifically, a group of comparators in the comparator array 103 having reference voltages near the predicted digital code is turned on, and the other comparators are turned off. As the number of comparators which are turned off increases, power consumption is reduced. The comparators are divided in such a manner that a predetermined number of comparators associated with continuous digital codes are defined as one group. Specifically, in the case where the comparator array is divided into two comparator groups, the two comparator groups are a comparator group associated with the upper half of an analog voltage and a comparator group associated with the lower half of the analog voltage. When the predicted value is in the range of the lower half, the comparator group associated with the upper half is turned off, and the comparator group associated with the lower half is turned on, thereby reducing power consumption of the comparator array to a half. Techniques relating to flash A/D converters are shown in Japanese Patent Publication No. H04-123523, Japanese Patent No. 2814362, and ISSCC2005 SESSION27.1, for example.

### SUMMARY

In the conventional flash A/D converters, however, if the next data coincides with the predicted value, A/D conversion can be accurately performed with reduction of power consumption. On the other hand, if the prediction fails to adequately predict the next data because of, for example, the influence of noise, the digital output signal considerably deviates from the actual value, and greatly affects the subsequent stages, resulting in a problem of continuous failures in predicting next data.

It is therefore an object of the present disclosure to prevent a digital output signal from deviating from an actual value to cause an extreme decrease in A/D conversion accuracy even when prediction fails, and thereby, to perform A/D conversion on an analog input signal with a certain degree of desired A/D conversion accuracy maintained.

To achieve the object, a flash A/D converter in an aspect of the present invention includes: a comparator array including a plurality of comparators each configured to compare an analog input signal and a reference voltage and output a result of comparison; a converter configured to convert the results of comparison from the comparators into a digital output signal; a predictor configured to predict a next level of the analog input signal based on the digital output signal from the converter and output prediction data; and a controller configured to turn on a predetermined number of comparators having reference voltages near the prediction data among the comparators in the comparator array, turn on at least one of the comparators in the comparator array according to a predetermined rule, and turn off the other comparators in the comparator array.

A flash A/D conversion module in another aspect of the present invention includes the above-described flash A/D converter; and a microcomputer configured to output, to the controller of the flash A/D converter, a range control signal specifying the predetermined number of comparators to be turned on having reference voltages near the prediction data, and an accuracy control signal specifying the predetermined rule.

In yet another aspect of the present invention, in the flash A/D conversion module, the controller of the flash A/D converter includes a prediction range controller configured to turn on part of the comparators having reference voltages near the prediction data in a number specified by the range control signal, based on the range control signal from the microcomputer and the prediction data from the predictor of the flash A/D converter.

In still another aspect of the present invention, in the flash A/D conversion module, the controller of the flash A/D converter includes an accuracy-ensuring controller configured to turn on part of the comparators in the comparator array, based on the accuracy control signal from the microcomputer.

In another aspect of the present invention, in the flash A/D conversion module, the microcomputer outputs an input waveform prediction specification signal specifying a method of prediction of the analog input signal in the predictor, and the controller of the flash A/D converter includes an input waveform predictor configured to receive the input waveform prediction specification signal from the microcomputer and predict a next level of the analog input signal in the method of prediction specified by the input waveform prediction specification signal.

A flash A/D converter in another aspect of the present invention includes: a comparator array including a plurality of comparators each configured to compare an analog input signal and a reference voltage and output a result of comparison; a converter configured to convert the results of comparison from the comparators into a digital output signal; a predictor configured to predict a next level of the analog input signal based on the digital output signal from the converter and output prediction data; and a controller configured to control the comparators such that the density of comparators to be turned on increases as the comparators have reference voltages closer to the prediction data among the comparators in the comparator array.

In another aspect of the present invention, the flash A/D converter or the flash A/D conversion module further includes a prediction determinator configured to determine whether the prediction by the predictor is accurate or not based on the prediction data from the predictor and the digital output signal from the converter, and when the prediction is not accurate, output a prediction failure signal, wherein the controller receives the prediction failure signal from the prediction determinator, and turns on a larger number of comparators among the comparators in the comparator array than that in normal operation.

A delta-sigma A/D converter in another aspect of the present invention includes: an analog adder configured to output a signal indicating a difference between an analog input signal and an analog feedback signal; an analog integrator configured to integrate the signal output from the analog adder; a multi-bit quantizer including the flash A/D converter or the flash A/D conversion module described above, and configured to quantize the signal output from the analog integrator with multiple bits and output a resultant signal; and a D/A converter configured to convert the signal output from the multi-bit quantizer into an analog signal, and output the analog signal as the analog feedback signal.

As described above, according to the present disclosure, next data of an analog input signal is predicted so that comparators with reference voltages near the prediction data are turned on and a certain number of comparators as well as the comparators near the prediction data are also turned on. Accordingly, even when the prediction data fails, a certain degree of desired A/D conversion accuracy can be ensured. This ensured A/D conversion accuracy varies depending on a circuit or other equipment to which the converter is applied. Thus, the number of comparators to be turned on except the comparators with reference voltages near the prediction data is changed according to A/D conversion accuracy to be ensured.

As descried above, in a flash A/D converter according to the present disclosure, a certain number of comparators are turned on in addition to comparators with reference voltages near prediction data. As a result, even when the prediction data fails, A/D conversion can be performed on an analog input signal with a certain degree of A/D conversion accuracy to be ensured.

### BRIEF DESCRIPTION OF THE DRAWINGS

FIG. 1 is a block diagram illustrating a configuration of a flash A/D converter according to a first embodiment of the present invention.

FIG. 2 is a block diagram illustrating a configuration of a flash A/D converter according to a second embodiment of the present invention.

FIG. 3 is a block diagram illustrating a configuration of a flash A/D converter according to a third embodiment of the present invention.

FIG. 4 is a block diagram illustrating an internal configuration of a controller provided in the flash A/D converter.

FIG. 5 is a block diagram illustrating a configuration of a ΔΣ A/D converter according to a fourth embodiment of the present invention.

FIG. 6 is a block diagram illustrating a configuration of a conventional flash A/D converter.

### DETAILED DESCRIPTION

Embodiments of the present disclosure will be described in detail with reference to the drawings.

### First Embodiment

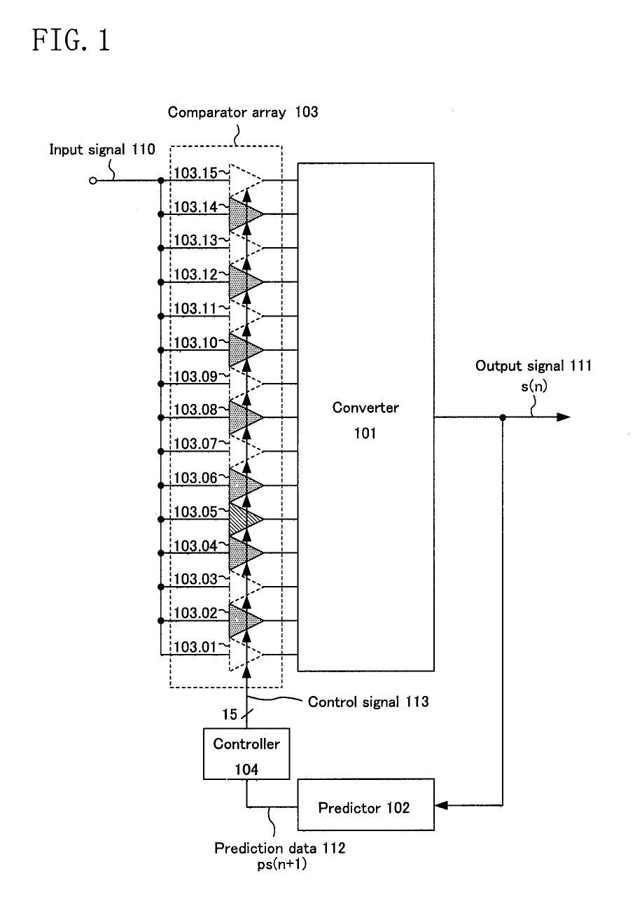

FIG. 1 illustrates a 4-bit flash A/D converter according to a first embodiment of the present invention.

In FIG. 1, reference character 110 denotes an analog input signal, reference character 103 denotes a comparator array, reference characters 103.01-103.15 denote comparators, reference character 101 denotes a converter, reference character 111 denotes a digital output signal, reference character 102 denotes a predictor, reference character 112 denotes prediction data, reference character 104 denotes a controller, and reference character 113 denotes a control signal.

The analog input signal 110 is input to each of the 15 comparators 103.01-103.15 in the comparator array 103, and a dedicated reference voltage (not shown) is previously input to each of the comparators. Each of the comparators compares the analog input signal 110 and the reference voltage input thereto, and outputs “high” when the value of the analog input signal 110 is higher than the reference voltage, and “low” when the value of the analog input signal 110 is lower than the reference voltage. The reference voltage increases in order from the comparator 103.01 to the comparator 103.15. The comparator in the off state outputs “low.”

The converter 101 receives the 15 comparison results obtained in the comparator array 103, and converts the results into a digital output signal 111. This conversion is performed in such a manner that the results are encoded as the digital output signal 111 based on the result from the comparator to which the highest reference voltage is input among the results from one or more comparators whose the reference voltages are determined to be lower than the analog input signal 110. For example, when the comparators 103.05-103.15 output “low” and the comparator 103.04 outputs “high,” the results are encoded as “0100.”

The predictor 102 predicts next data using the digital output signal 111, and outputs prediction data 112 ps(n+1). This prediction can be performed in various ways. For example, the predictor 102 predicts next data assuming that the prediction data ps(n+1)=previous data s(n). This process is effective when the sampling rate is significantly high with respect to the analog input signal 110, and the analog input signal can be considered as DC. When the change in the analog input signal 110 is constant, the predictor 102 predicts that ps(n+1)=s(n)+(s(n)−s(n−1)). In this prediction, the analog input signal 110 can be accurately predicted. In this manner, as the analog input signal 110 becomes more complicated, the more previous data s(n−x) is used, thereby accurately predicting the prediction data ps(n+1). The predictor 102 employs and adjusts an appropriate prediction process according to characteristics of the analog input signal 110.

The controller 104 receives the prediction data 112 from the predictor 102, and outputs a control signal 113 for controlling on/off of the 15 comparators 103.01-103.15 in the comparator array 103 in such a manner that when the prediction of the prediction data 112 is accurate, A/D conversion is highly accurately performed, and moreover, even when the next analog input signal 110 does not match the prediction data 112, a certain degree of desired A/D conversion accuracy is maintained according to a predetermined rule. For example, in the case of 4-bit A/D conversion illustrated in FIG. 1, the number of comparators 103.01-103.15 is 15. Accordingly, if the desired A/D conversion accuracy is 3 bits, only the even-numbered comparators 103.2a (where a is 0 to 7) need to be turned on. Thus, the even-numbered comparators 103.2a (where a is 0 to 7) are turned on according to the predetermined rule. If the prediction data 112 is at the reference level of the comparator 103.05, the comparators 103.04-103.06 are additionally turned on. In this case, since the even-numbered comparators 103.04 and 103.06 are already turned on, only the comparator 103.05 is additionally turned on, and the other comparators are turned off. In this manner, when the analog input signal 110 is within the reference levels of the comparators 103.04-103.06 and the prediction is accurate, conversion can be performed with 4-bit accuracy. Even when the prediction fails, the even-numbered comparators 103.2a (where a is 0 to 7) can perform A/D conversion with 3-bit accuracy.

In the case where the A/D conversion accuracy also desired when prediction fails is low, an increase in the distance between comparators to be turned on in order to ensure desired accuracy can further reduce power consumption.

To further ensure A/D conversion with high accuracy, the range of comparators to be turned on based on the prediction data 112 can be increased. For example, not only comparators 103.04-103.06 but also the peripheral comparators 103.03-103.07 may be turned on.

When the prediction accuracy is high, comparators to be turned on may be defined in such a manner that comparators whose reference voltages are closer to the prediction data are turned on in a larger number, and comparators whose reference voltages are more discrete from the prediction data are turned on in a smaller number (i.e., the density of comparators to be turned on increases as the comparators to be turned have reference voltages closer to the prediction data among the comparators in the comparator array). For example, in the case where the prediction data 112 is at the reference voltage level of the comparator 103.05, the comparators 103.04-103.06 at successive positions, the comparators 103.02 and 103.08 respectively spaced apart from the comparators 103.04 and 103.06 each with one comparator sandwiched therebetween, the comparator 103.11 spaced apart from the comparator 103.08 with two comparators sandwiched therebetween, and the comparator 103.15 spaced apart from the comparator 103.11 with three comparators sandwiched therebetween, may be turned on.

In this manner, comparators which are arranged at continuous positions and have reference voltages near the prediction data 112 are turned on, and other comparators at discrete positions are turned on, thereby enabling conversion with high accuracy in the case of accurate prediction and with minimum ensured accuracy in the case of inaccurate prediction.

### Second Embodiment

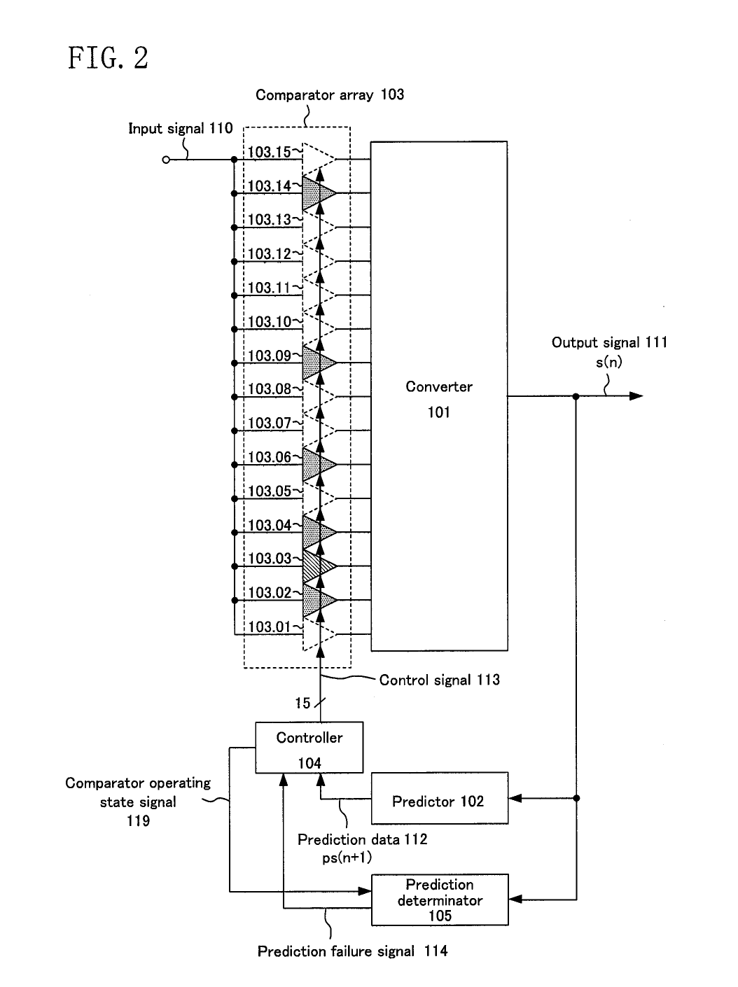

FIG. 2 shows a second embodiment of the present invention. In FIG. 2, reference characters 101-103 and 110-113 denote the same components as 101-104 and 110-113 in FIG. 1, and thus, description thereof will not be repeated. Reference character 105 denotes a prediction determinator, reference character 114 denotes a prediction failure signal, and reference character 119 denotes a comparator operating state signal.

The controller 104 outputs the comparator operating state signal 119 indicating comparators in on states in the comparator array 103, in addition to the control described in the first embodiment.

The prediction determinator 105 determines whether or not a digital output signal 111 s(n+1) from the converter 101 is within the range predicted by prediction data 112 using the comparator operating state signal 119 from the controller 104 and the digital output signal 111 s(n+1). When the digital output signal 111 s(n+1) is not within the range, i.e., the prediction fails, the prediction determinator 105 outputs a prediction failure signal 114. Specifically, when the digital output signal 111 s(n+1) indicates that the output from the comparator 103.05 is “high,” the output from the comparator 103.06 is “low,” and the comparator 103.06 is determined not to be in the on state based on the comparator operating state signal 119, the prediction determinator 105 determines that the digital output signal 111 s(n+1) is not within the predicted range, and outputs the prediction failure signal 114.

When receiving the prediction failure signal 114 from the prediction determinator 105, irrespective of the prediction data 112 from the predictor 102, the controller 104 outputs a control signal 113 such that a larger number of comparators than in normal operation are turned on at least in a sampling period corresponding to the order of the predictor 102 (i.e., the order of how many preceding stages of data is used, e.g., x+1 when data up to s(n−x) is used to predict prediction data 1.12 ps(n+1)). In this case, all the comparators 103.01-103.15 are preferably turned on. Alternatively, the comparators 103.2a (where a is 0 to 7) may be turned on in such a manner that in the case where the comparators 103.04, 103.08, and 103.12 are turned on during normal operation in order to maintain 2-bit accuracy, when prediction fails, 3-bit accuracy is ensured, for example.

A failure in prediction makes it difficult to accurately perform next prediction. Thus, a larger number of comparators 103.01-103.15 than in normal operation are turned on until the predictor 102 performs accurate prediction again (i.e., all the data in the predictor 102 becomes accurate data). In this manner, even when prediction fails, the time before next accurate prediction can be reduced.

### Third Embodiment

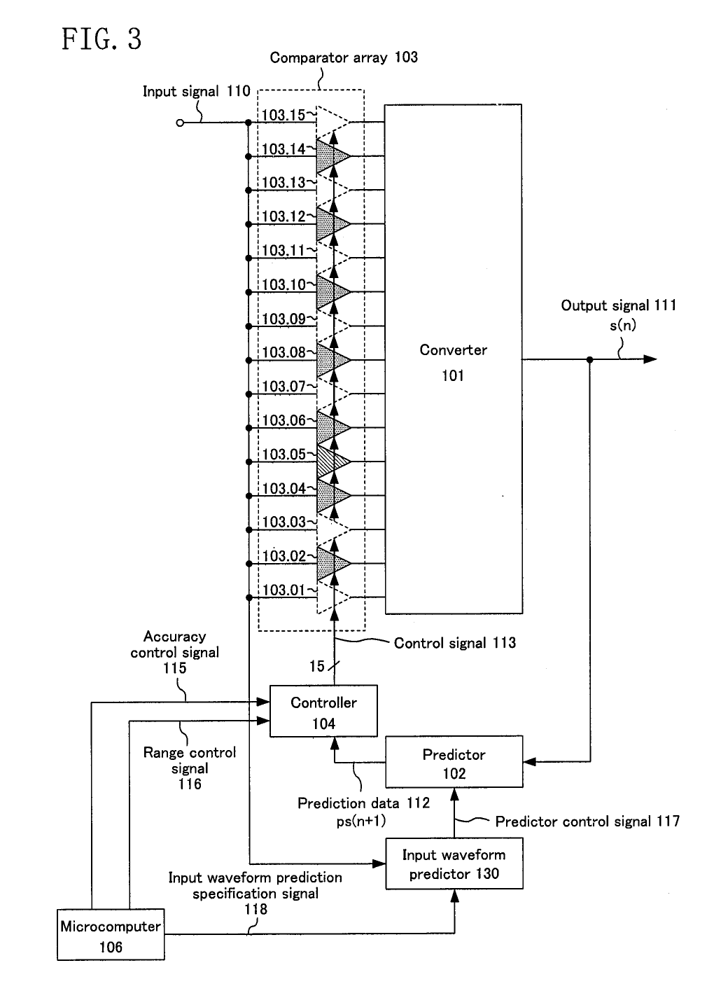

FIG. 3 shows a third embodiment of the present invention. In this embodiment, the configuration of the converter is described in more detail than in the first embodiment.

In the flash A/D conversion module illustrated in FIG. 3, reference characters 101-104 and 110-113 denote the same components as 101-104 and 110-113 in FIG. 1, and thus, description thereof will not be repeated. Reference character 106 denotes a microcomputer, reference character 130 denotes an input waveform predictor, reference character 115 denotes an accuracy control signal, reference character 116 denotes a range control signal, reference character 117 denotes a predictor control signal, and reference character 118 denotes an input waveform prediction specification signal.

The microcomputer 106 outputs the accuracy control signal 115, the range control signal 116, and the input waveform prediction specification signal 118. The accuracy control signal 115 is a signal specifying a predetermined rule such that a certain degree of A/D conversion accuracy (hereinafter referred to as an ensured accuracy) desired even when prediction fails. The range control signal 116 is a signal output from the predictor 102 and specifying turning-on of a predetermined number of comparators with reference voltages near the prediction data 112 (i.e., a signal specifying a predetermined number). The input waveform prediction specification signal 118 is a signal specifying a method of prediction of a next input waveform in the predictor 102.

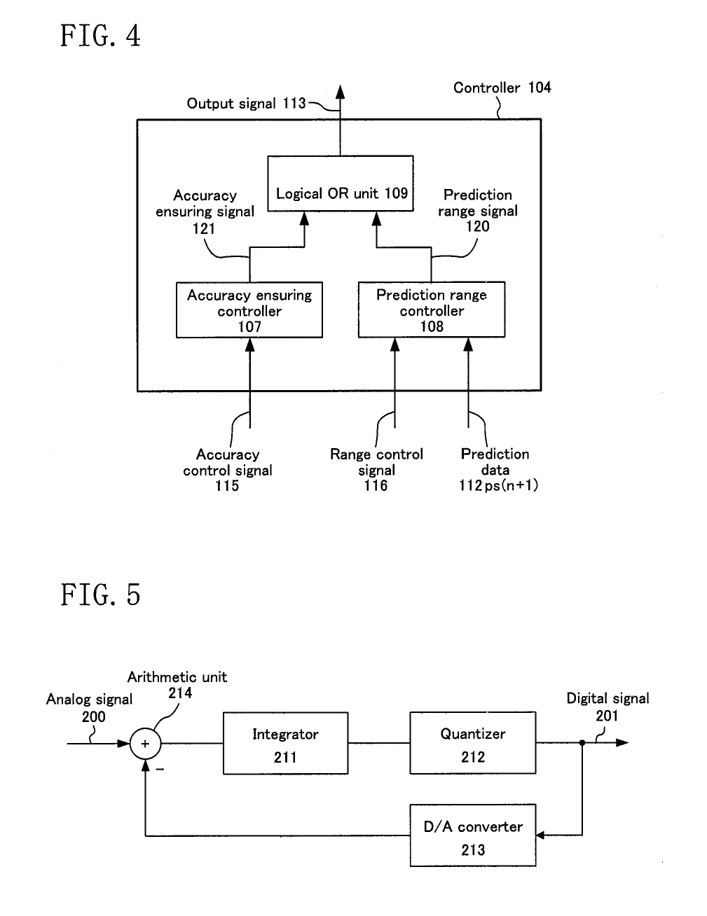

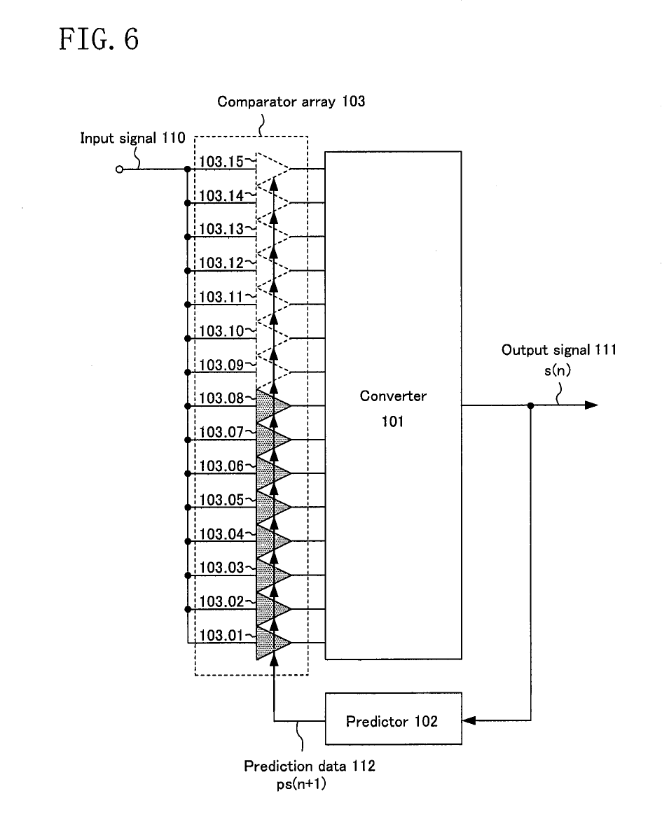

FIG. 4 is a block diagram illustrating an internal configuration of the controller 104. In FIG. 4, the controller 104 includes an accuracy-ensuring controller 107, a prediction range controller 108, and a logical OR unit 109. The accuracy-ensuring controller 107 receives an ensured accuracy with an accuracy control signal 115 from the microcomputer 106, and outputs an accuracy ensuring signal 121 for determining comparators to be turned on. Specifically, based on the accuracy control signal 115 from the microcomputer 106, if the ensured accuracy is 3 bits, the accuracy ensuring signal 121 for turning on even-numbered comparators 103.2a (where a is 0 to 7), as a predetermined rule.

In response to the prediction data 112 from the predictor 102 and the range control signal 116 from the microcomputer 106, the prediction range controller 108 outputs a prediction range signal 120 for determining a predetermined number of comparators to be turned on based on prediction. For example, if the prediction data 112 at the reference level of the comparator 103.05 and the range control signal 116 indicates the number “3,” three comparators 103.04-103.06 are turned on.

The logical OR unit 109 outputs a control signal 113 for turning on comparators to be turned on in response to one of the accuracy ensuring signal 121 from the accuracy-ensuring controller 107 and the prediction range signal 120 from the prediction range controller 108. For example, in the case where the comparators 103.2a (where a is 0 to 7) are turned on in response to the accuracy ensuring signal 121 and the comparators 103.04-103.06 are turned on in response to the prediction range signal 120, the control signal 113 indicates that the comparators 103.00, 103.02, 103.04, 103.05, 103.06, 103.08, 103.10, 103.12, and 103.14 are turned on.

Returning to FIG. 3, when receiving the input waveform prediction specification signal 118 from the microcomputer 106, the input waveform predictor 130 predicts an input waveform based on the analog input signal 110, and outputs a predictor control signal 117 for controlling the configuration of the predictor 102 in order to make prediction data 112 accurate. For example, in the case where the analog input signal 110 is DC, the predictor 102 is controlled such that the prediction data ps(n+1)=previous data ps(n).

In this embodiment, a detailed configuration of the flash A/D converter illustrated in FIG. 1 has been described. This detailed configuration may be, of course, applied to the flash A/D converter illustrated in FIG. 2.

### Fourth Embodiment

FIG. 5 shows a fourth embodiment of the present invention. In this embodiment, an example in which the flash A/D converter of the first through third embodiments is applied to a ΔΣ A/D converter is described.

FIG. 5 is a block diagram illustrating a configuration of the ΔΣ A/D converter. In FIG. 5, reference character 200 denotes an analog input signal, reference character 201 denotes a digital signal, reference character 211 denotes an analog integrator, reference character 212 denotes a multi-bit quantizer, reference character 213 denotes a D/A converter, and reference character 214 denotes an arithmetic unit.

The arithmetic unit (analog adder) 214 computes a difference between the analog input signal 200 and an analog feedback signal from the D/A converter 213, and outputs the obtained difference signal. The integrator 211 integrates the output signal from the arithmetic unit 214. The multi-bit quantizer 212 quantizes the output signal from the integrator 211 with multiple bits, and outputs the result. The multi-bit quantizer 212 includes one of the flash A/D converters of the first through third embodiments. The D/A converter 213 converts the output signal from the multi-bit quantizer 212 into an analog signal, and outputs the analog signal as the analog feedback signal to the arithmetic unit 214.

A ΔΣ A/D converter has a problem in which when an error in the quantizer 212 is large, an error in feedback amount is also large to cause oscillation. Accordingly, when prediction fails as in the conventional converters, a large digital output signal with an error causes the ΔΣ A/D converter to oscillate. To prevent this problem, the use of the flash A/D converter of one of the first through third embodiments reduces the error in feedback amount, and prevents the ΔΣ A/D converter from oscillating, even when prediction fails.

As described above, according to the present disclosure, a certain degree of A/D conversion accuracy desired even when prediction fails can be maintained. Thus, the present disclosure is useful for a flash A/D converter, and especially for a ΔΣ A/D converter.

1. A flash A/D converter, comprising:
a comparator array including a plurality of comparators each configured to compare an analog input signal and a reference voltage and output a result of comparison;
a converter configured to convert the results of comparison from the comparators into a digital output signal;
a predictor configured to predict a next level of the analog input signal based on the digital output signal from the converter and output prediction data; and
a controller configured to turn on a predetermined number of comparators having reference voltages near the prediction data among the comparators in the comparator array, turn on at least one of the comparators in the comparator array according to a predetermined rule, and turn off the other comparators in the comparator array.

2. A flash A/D conversion module, comprising:
the flash A/D converter of claim 1; and
a microcomputer configured to output, to the controller of the flash A/D converter, a range control signal specifying the predetermined number of comparators to be turned on having reference voltages near the prediction data, and an accuracy control signal specifying the predetermined rule.

3. The flash A/D conversion module of claim 2, wherein
the controller of the flash A/D converter includes
a prediction range controller configured to turn on part of the comparators having reference voltages near the prediction data in a number specified by the range control signal, based on the range control signal from the microcomputer and the prediction data from the predictor of the flash A/D converter.

4. The flash A/D conversion module of claim 2, wherein the controller of the flash A/D converter includes an accuracy-ensuring controller configured to turn on part of the comparators in the comparator array, based on the accuracy control signal from the microcomputer.

5. The flash A/D conversion module of claim 2, wherein
the microcomputer outputs an input waveform prediction specification signal specifying a method of prediction of the analog input signal in the predictor, and
the controller of the flash A/D converter includes an input waveform predictor configured to receive the input waveform prediction specification signal from the microcomputer and predict a next level of the analog input signal in the method of prediction specified by the input waveform prediction specification signal.

6. A flash A/D converter, comprising:
a comparator array including a plurality of comparators each configured to compare an analog input signal and a reference voltage and output a result of comparison;
a converter configured to convert the results of comparison from the comparators into a digital output signal;
a predictor configured to predict a next level of the analog input signal based on the digital output signal from the converter and output prediction data; and
a controller configured to control the comparators such that the density of comparators to be turned on increases as the comparators have reference voltages closer to the prediction data among the comparators in the comparator array.

7. The flash A/D converter or the flash A/D conversion module of claim 1, further comprising a prediction determinator configured to determine whether the prediction by the predictor is accurate or not based on the prediction data from the predictor and the digital output signal from the converter, and when the prediction is not accurate, output a prediction failure signal, wherein
the controller receives the prediction failure signal from the prediction determinator, and turns on a larger number of comparators among the comparators in the comparator array than that in normal operation.

8. A delta-sigma A/D converter, comprising:
an analog adder configured to output a signal indicating a difference between an analog input signal and an analog feedback signal;
an analog integrator configured to integrate the signal output from the analog adder;
a multi-bit quantizer including the flash A/D converter or the flash A/D conversion module of claim 1, and configured to quantize the signal output from the analog integrator with multiple bits and output a resultant signal; and
a D/A converter configured to convert the signal output from the multi-bit quantizer into an analog signal, and output the analog signal as the analog feedback signal.
